(19) United States
(12) Patent Application Publication
(10) Pub. No.: US 2023/0245854 A1
(43) Pub. Date: Aug. 3, 2023

(54) HYBRID LIQUID/AIR COOLING SYSTEM FOR TCP WINDOWS

(71) Applicant: LAM RESEARCH CORPORATION, Fremont, CA (US)

(72) Inventors: Andrea ALBERTI, Milpitas, CA (US); Saravanapriyan SRIRAMAN, Fremont, CA (US); John DREWERY, San Jose, CA (US); Alexander Miller PATERSON, San Jose, CA (US)

(21) Appl. No.: 18/013,736

(22) PCT Filed: Feb. 7, 2022
(86) PCT No.: PCT/US2022/015479

§ 371 Date: Dec. 29, 2022

Related U.S. Application Data
(60) Provisional application No. 63/147,802, filed on Feb. 10, 2021.

(51) Int. Cl. H01J 37/32

(52) U.S. Cl. CPC H01J 37/32119; H01J 37/3244; H01J 37/32522

(57) ABSTRACT

A dielectric window assembly for a substrate processing system includes a dielectric window, a Faraday shield that is one of adjacent to the dielectric window, embedded within the dielectric window, and arranged in a recess in an upper surface of the dielectric window, and cooling channels arranged within the Faraday shield. The cooling channels are configured to flow coolant throughout the Faraday shield.

### CROSS-REFERENCE TO RELATED APPLICATIONS

This application claims the benefit of U.S. Provisional Application No. 63/147,802, filed on Feb. 10, 2021. The entire disclosure of the application referenced above is incorporated herein by reference.

### FIELD

The present disclosure relates to gas distribution devices for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During manufacturing of substrates such as semiconductor wafers, etch processes and deposition processes may be performed within a processing chamber. The substrate is disposed in the processing chamber on a substrate support such as an electrostatic chuck (ESC) or a pedestal. Process gases are introduced via a gas distribution device and plasma is struck in the processing chamber.

### SUMMARY

A dielectric window assembly for a substrate processing system includes a dielectric window, a Faraday shield that is one of adjacent to the dielectric window, embedded within the dielectric window, and arranged in a recess in an upper surface of the dielectric window, and cooling channels arranged within the Faraday shield. The cooling channels are configured to flow coolant throughout the Faraday shield.

In other features, the Faraday shield is adjacent to the dielectric window. The dielectric window includes the recess defined in the upper surface of the dielectric window and the Faraday shield is arranged in the recess. An upper surface of the Faraday shield is coplanar with the upper surface of the dielectric window. An upper surface of the Faraday shield is not coplanar with the upper surface of the dielectric window.

In other features, the Faraday shield is embedded within the dielectric window. The dielectric window includes a bottom plate, a top plate, and a cavity defined between the bottom plate and the top plate. The Faraday shield is arranged within the cavity between the bottom plate and the top plate. The cooling channels include copper tubes. The dielectric window is generally flat. The dielectric window is dome-shaped and includes a generally flat interior region and a curved outer region.

In other features, a gas distribution assembly includes the dielectric window assembly and further includes a gas plate arranged below the dielectric window, wherein a plenum is defined between the dielectric window and the gas plate. The cooling channels include a plurality of rings and at least one connecting rod that provides fluid communication between individual ones of the plurality of rings.

In other features, a system includes the dielectric window assembly and further includes a liquid cooling system in fluid communication with the cooling channels. The liquid cooling system is configured to supply coolant to the cooling channels via a supply tube. The system further includes an air cooling system configured to circulate air around an outer region of the dielectric window.

A system includes a dielectric window assembly for a substrate processing chamber. The dielectric window assembly includes a dielectric window including an interior region and an outer region and a Faraday shield that is arranged in the interior region of the dielectric window and that is one of adjacent to the dielectric window, embedded within the dielectric window, and arranged in a recess in an upper surface of the dielectric window. Cooling channels arranged within the Faraday shield are configured to flow coolant throughout the Faraday shield. An air cooling system is configured to circulate air around the outer region of the dielectric window.

In other features, the dielectric window is dome-shaped, the interior region is generally flat, and the outer region is curved. The system further includes a gas plate arranged below the dielectric window and a plenum is defined between the dielectric window and the gas plate. The cooling channels include a plurality of rings and at least one connecting rod that provides fluid communication between individual ones of the plurality of rings. The system further includes a liquid cooling system in fluid communication with the cooling channels. The liquid cooling system is configured to supply coolant to the cooling channels via a supply tube.

A dielectric window assembly for a substrate processing system includes a dielectric window and at least one cooling channel arranged within the dielectric window. The at least one cooling channel is configured to flow coolant throughout the dielectric window.

In other features, the at least one cooling channel comprises a plurality of cooling channels. The cooling channel includes a disc-shaped cavity defined within a body of the dielectric window. The dielectric window is comprised of ceramic and the cooling channel is defined within the ceramic. At least one support column is arranged within the cooling channel. The at least one support column extends from a lower surface of the cooling channel to an upper surface of the cooling channel.

In other features, a system includes the dielectric window assembly, a liquid cooling system that is in fluid communication with the at least one cooling channel and is configured to supply coolant to the at least one cooling channel via a supply tube, and an air cooling system configured to circulate air around an outer region of the dielectric window.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system including a gas distribution device according to the present disclosure;

FIGS. 2A, 2B, and 2C are example dielectric windows including a Faraday shield according to the present disclosure;

FIG. 3A is an example dome-shaped dielectric window including a Faraday shield according to the present disclosure;

FIG. 3B shows example cooling channels of the dielectric window of FIG. 3A;

FIG. 3C is an isometric view of the dielectric window of FIG. 3A;

FIG. 3D shows an example of a dielectric window including a cooling channel defined within a material of the dielectric window; and

FIGS. 4A, 4B, and 4C are example cooling channel configurations according to the present disclosure.

In the drawings, reference numbers may be reused to identify similar and/or identical elements.

### DETAILED DESCRIPTION

Substrate processing systems may include a gas distribution device (e.g., a showerhead) arranged in a lid or upper surface of a processing chamber. In processing chambers configured to perform transformer coupled plasma (TCP) processing, the gas distribution device may correspond to a gas distribution assembly including a gas plate (e.g., a showerhead plate) arranged to face an interior of the processing chamber and a dielectric window arranged above the gas plate. The dielectric window may be generally flat or, in some examples, dome-shaped. A plenum may be defined between the gas plate and the dielectric window. Process gas is supplied to the processing chamber via the gas distribution device and plasma is generated inside of the processing chamber. For example, an RF signal is transmitted from TCP coils through the dielectric window into the interior of the processing chamber. The RF signal transmitted from the TCP coils heats the dielectric window.

In some examples, temperatures of the gas distribution assembly may be controlled to minimize mechanical stress, maintain process uniformity, etc. For example, a plenum may be arranged above the dielectric window and air is circulated within the plenum to cool the dielectric window. In some systems, relatively high air flow (e.g., 200 cubic feet per minute (CFM) or more per processing chamber) may be required to provide sufficient cooling of the dielectric window, resulting in undesirable noise levels. Further, as power of the RF signal increases, temperature and mechanical stress also increase and cooling provided by high air flow may be insufficient.

A gas distribution assembly according to the present disclosure implements a temperature control system that provides improved cooling of the dielectric window, improves temperature distribution, and reduces system noise and mechanical stress caused by high temperatures. For example, the dielectric window includes a Faraday shield adjacent to or embedded within the dielectric window. At least one of the Faraday shield and the dielectric window may include cooling channels configured to flow a cooling liquid (e.g., water).

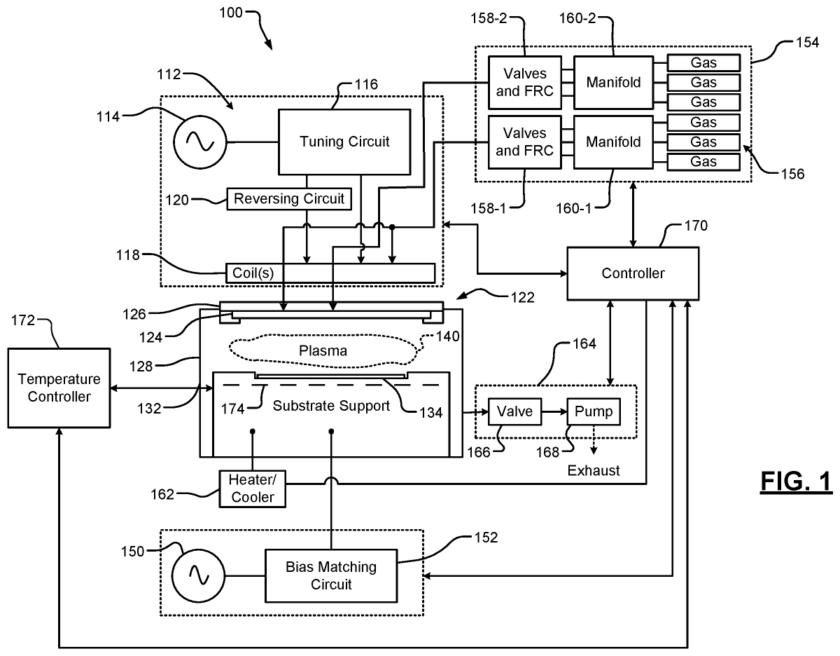

Referring now to FIG. 1, an example of a substrate processing system 100 according to certain embodiments of the present disclosure is shown. The substrate processing system 100 includes a coil driving circuit 112. As shown, the coil driving circuit 112 includes an RF source 114 and a tuning circuit 116. The tuning circuit 116 may be directly connected to one or more inductive transformer coupled plasma (TCP) coils 118. Alternatively, the tuning circuit 116 may be connected by an optional reversing circuit 120 to one or more of the coils 118. The tuning circuit 116 tunes an output of the RF source 114 to a desired frequency and/or a desired phase, matches an impedance of the coils 118 and splits power between the TCP coils 118. The reversing circuit 120 is used to selectively switch the polarity of current through one or more of the TCP coils 118. In some examples, the coil driving circuit 112 implements a transformer coupled capacitive tuning (TCCT) match network to drive the TCP coils 118.

A gas distribution device or assembly 122 includes a showerhead (e.g., a gas plate) 124 and a dielectric window 126. Although shown as generally flat, in some examples the dielectric window 126 may be dome-shaped. For example, a plenum may be defined between the gas plate 124 and the dielectric window 126. The gas plate 124 is arranged between the dielectric window 126 and a processing chamber 128. In some embodiments, the dielectric window 126 contains ceramic. In some embodiments, the gas plate 124 comprises ceramic or another dielectric material.

The processing chamber 128 further comprises a substrate support (or pedestal) 132. The substrate support 132 may include an electrostatic chuck (ESC), or a mechanical chuck or other types of chuck. In operation, a process gas is supplied to the processing chamber 128 via the gas plate 124 (e.g., a plurality of holes passing through the gas plate) and plasma 140 is generated inside of the processing chamber 128. For example, an RF signal is transmitted from the TCP coils through the dielectric window 126 into the interior of the processing chamber 128. The RF signal excites gas molecules within the processing chamber 128 to generate plasma 140. The plasma 140 etches an exposed surface of the substrate 134. An RF source 150 and a bias matching circuit 152 may be used to bias the substrate support 132 during operation to control ion energy.

A gas delivery system 154 may be used to supply a process gas mixture to the processing chamber 128. The gas delivery system 154 may include process and inert gas sources 156 (e.g., including deposition gases, etch gases, carrier gases, inert gases, etc.), gas metering systems 158-1 and 158-2 such as valves and flow ratio controllers (e.g., mass flow controllers (MFCs)), and respective manifolds 160-1 and 160-2. For example, the gas metering system 158-1 and the manifold 160-1 may be arranged to provide etch gas mixtures to the processing chamber 128 during etching while the gas metering system 158-2 and the manifold 160-2 may be arranged to provide deposition gas mixtures to the processing chamber 128 during deposition. For example, the etch and deposition gas mixtures may be provided to the plenums of the gas plate 124 through the coil 118 and via respective passages in the dielectric window 126. A heater/cooler 162 may be used to heat/cool the substrate support 132 to a predetermined temperature. An exhaust system 164 includes a valve 166 and pump 168 to remove reactants from the processing chamber 128 by purging or evacuation.

A controller 170 may be used to control the etching process. The controller 170 monitors system parameters and controls delivery of the gas mixture, striking, maintaining and extinguishing the plasma, removal of reactants, and so on. Additionally, the controller 170 may control various aspects of the coil driving circuit 112, the RF source 150, and the bias matching circuit 52, etc. In some embodiments, the substrate support 132 is temperature-tunable. In certain embodiments, a temperature controller 172 may be connected to a plurality of heating elements 174, such as thermal control elements (TCEs), arranged in the substrate support 132. The temperature controller 172 may be used to control the plurality of heating elements 174 to control a temperature of the substrate support 132 and the substrate 134.

The dielectric window 126 according to the present disclosure may include a Faraday shield (not shown in FIG. 1) adjacent to or embedded within the dielectric window 126. At least one of the Faraday shield and the dielectric window 126 may include cooling channels configured to flow a cooling liquid as described below in more detail.

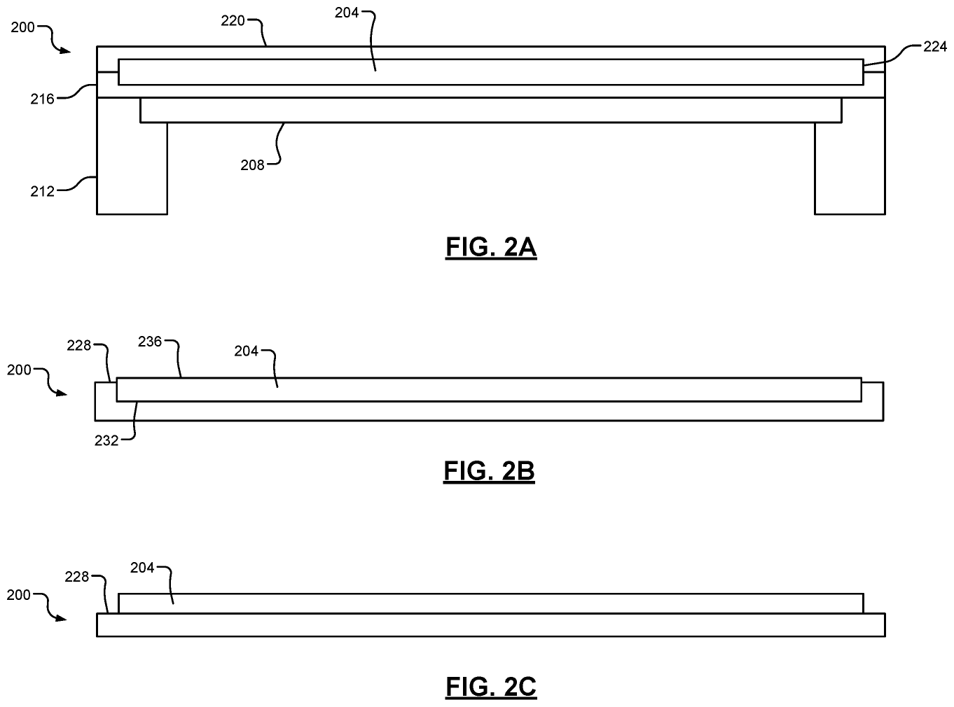

Referring now to FIG. 2A, a dielectric window assembly including an example dielectric window 200 according to the present disclosure is shown. The dielectric window 200 includes a Faraday shield 204. For example, the Faraday shield 204 may be comprised of copper. A showerhead or gas plate 208 is supported on sidewalls 212 of a processing chamber (e.g., the processing chamber 128 of FIG. 1) and the dielectric window 200 is arranged on the gas plate 208. In this example, the dielectric window 200 includes a bottom plate 216 and a top plate 220 arranged on the bottom plate 216. A cavity 224 is defined between the bottom plate 216 and the top plate 220. The Faraday shield 204 is arranged in the cavity 224. Accordingly, the Faraday shield 204 is embedded within the dielectric window 200 between the bottom plate 216 and the top plate 220. In some examples, a thermal paste or gel may be provided in the cavity 224 between surfaces of the Faraday shield 204 and the dielectric window 200.

Conversely, as shown in FIG. 2B, an upper surface 228 of the dielectric window 200 may include a recess 232 and the Faraday shield 204 is arranged in the recess 232. For example, the Faraday shield 204 may be fastened to the dielectric window 200 using fasteners such as ceramic screws, a thermal adhesive, etc. In an example, the Faraday shield 204 is fastened to the dielectric window 200 using screws and a thermal paste or gel is provided between the Faraday shield 204 and the dielectric window 200. An upper surface 236 of the Faraday shield 204 may be slightly above or below (i.e., offset in vertical direction from) the upper surface 228 of the dielectric window 200 (as shown in FIG. 2B). In other examples, the upper surface 236 of the Faraday shield 204 may be flush (i.e., coplanar) with the upper surface 228 of the dielectric window 200.

In another example shown in FIG. 2C, the Faraday shield 204 is arranged on the dielectric window 200 (i.e., on the upper surface 228 of the dielectric window 200). For example, the Faraday shield 204 may be fastened to the dielectric window 200 using fasteners such as ceramic screws, a thermal adhesive, etc. In an example, the Faraday shield 204 is fastened to the dielectric window 200 using screws and a thermal paste or gel is provided between the Faraday shield 204 and the dielectric window 200.

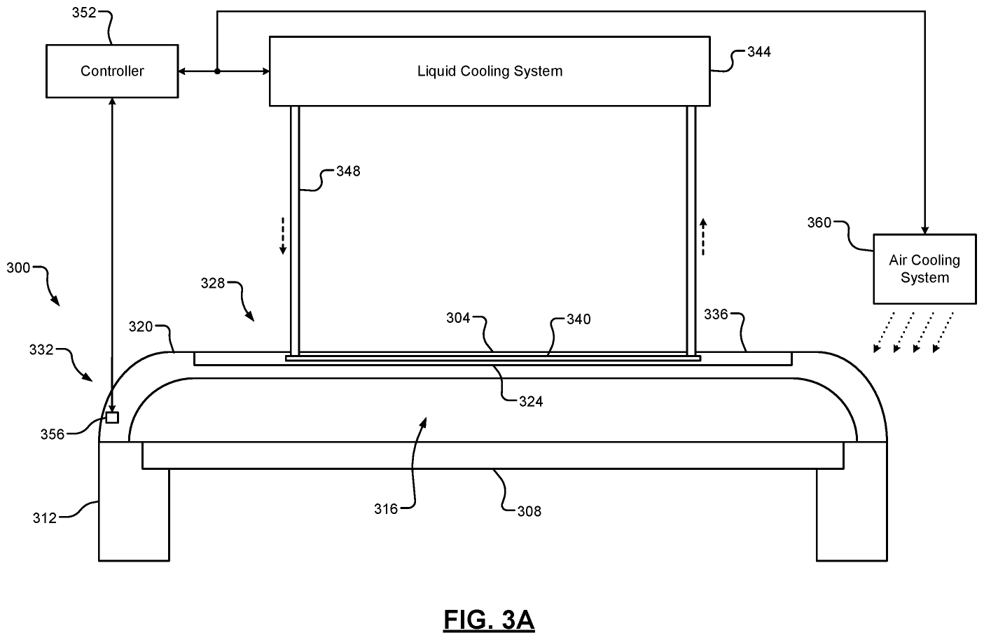

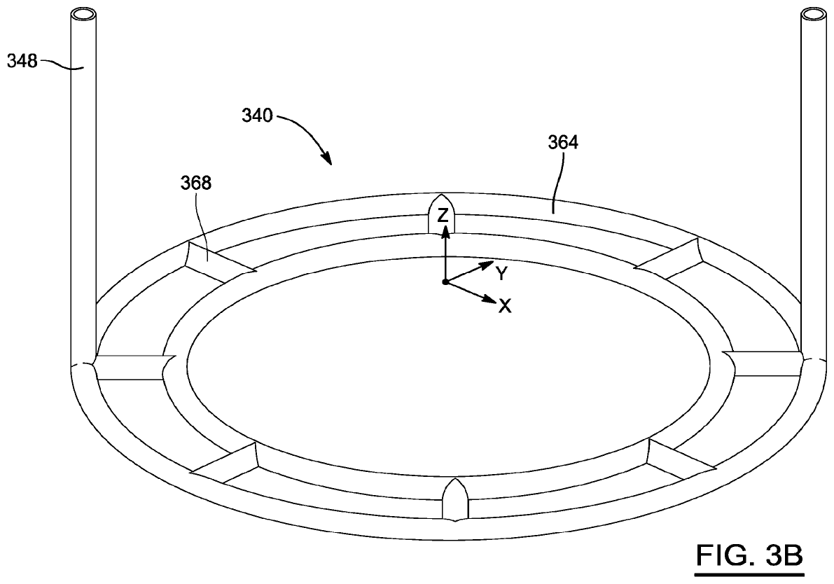

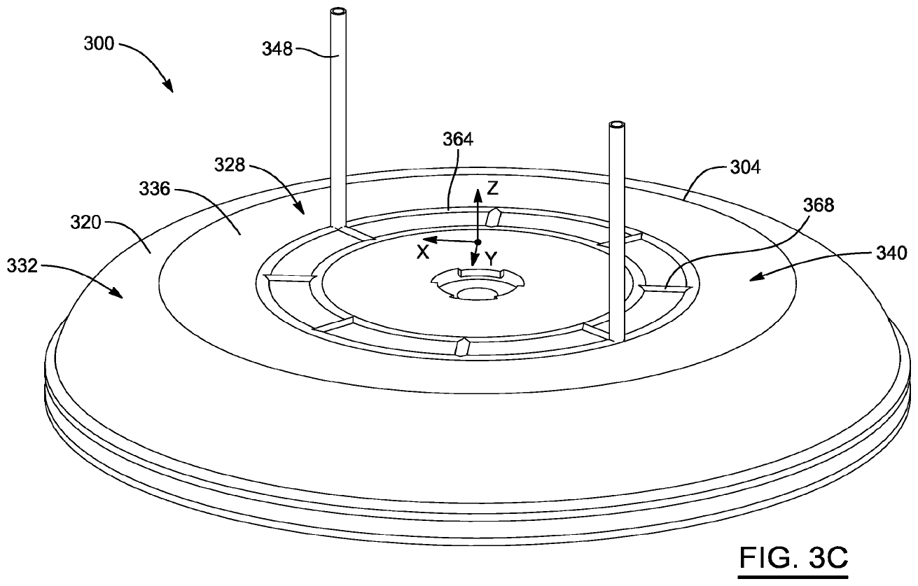

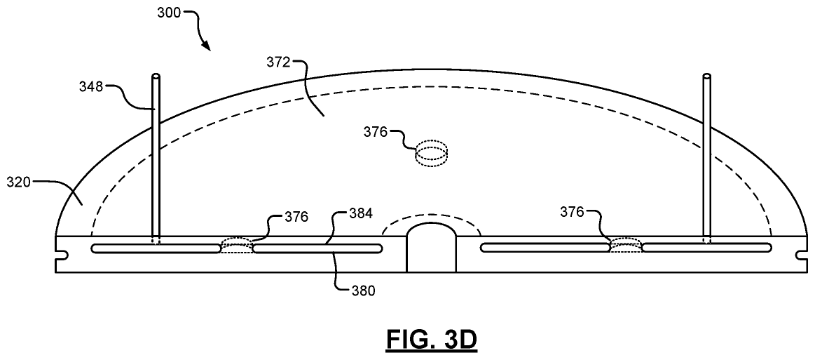

Although shown as being generally flat in FIGS. 2A, 2B, and 2C, an example dielectric window 300 including a Faraday shield 304 may be dome-shaped as shown in FIG. 3A. For example, the Faraday shield 304 may be comprised of copper. A showerhead or gas plate 308 is supported on sidewalls 312 of a processing chamber (e.g., the processing chamber 128 of FIG. 1) and the dielectric window 300 is arranged on the gas plate 308. The dielectric window 300 defines a plenum 316 between the dielectric window 300 and the gas plate 308. Any of the example arrangements of the Faraday shield 204 of FIGS. 2A, 2B, and 2C may be implemented in the dome-shaped dielectric window 300.

As shown in FIG. 3A, an upper surface 320 of the dielectric window 300 includes a recess 324 and the Faraday shield 304 is arranged in the recess 324. For example, the dielectric window 300 includes a generally flat interior region 328 and a curved or arcuate outer region 332. The recess 324 is defined in the flat interior region 328.

The Faraday shield 304 may be fastened to the dielectric window 300 using fasteners such as ceramic screws, a thermal adhesive, etc. In an example, the Faraday shield 304 is fastened to the dielectric window 300 using screws and a thermal paste or gel is provided between the Faraday shield 304 and the dielectric window 300. An upper surface 336 of the Faraday shield 304 may be slightly above or below (i.e., offset in vertical direction from) the upper surface 320 of the dielectric window 300. In other examples, the upper surface 336 of the Faraday shield 304 may be flush (i.e., coplanar) with the upper surface 320 of the dielectric window 300.

The Faraday shield 304 includes cooling channels 340 configured to flow a cooling liquid (e.g., a coolant such as water) to control a temperature of the dielectric window 300. A liquid cooling system 344 (e.g., a liquid storage tank in fluid communication with the cooling channels 340 via associated valves, flow controllers, etc.) supplies the coolant to the cooling channels 340 via one or more supply tubes 348. For example, the coolant flows from the liquid cooling system 344 into the cooling channels 340 via one of the tubes 348 and from the cooling channels 340 back into the liquid cooling system 344 via another one of the tubes 348. The supply tubes 348 may comprise a same material (e.g., aluminum) as the cooling channels 340 or a different material.

In one example, the cooling channels 340 comprise aluminum tubes embedded within the Faraday shield 304. In another example, the cooling channels 340 are channels engraved or machined directly into the material of the Faraday shield 304. In this example, the coolant is in direct contact with the material of the Faraday shield 304. In examples where the cooling channels 340 are formed directly within the dielectric window 300, the coolant is in direct contact with the material of the dielectric window 300 (e.g., ceramic).

A controller 352 (e.g., the controller 170, the temperature controller 172, etc.) may be configured to control components of the liquid cooling system 344 to supply the coolant to the cooling channels 340. For example, the controller 352 may receive temperature measurements from one or more temperature sensors 356 on or embedded within the dielectric window 300, the Faraday shield 304, etc. and control flow of coolant based on the temperature measurements. In other examples, the controller 352 is configured to calculate or estimate the temperature of the dielectric window 300.

An optional air cooling system 360 is configured to circulate air around the outer region 332 of the dielectric window 300 to provide additional cooling. In other words, the cooling channels 340 may be provided only in the flat interior region 328 of the dielectric window 300 and not in the curved outer region 332. For example, the curved outer region 332 may experience increased mechanical stress caused by temperature fluctuations. Further, modifications to the structure of the dielectric window 300 in the curved outer region 332 (e.g., modifications associated including portions of the Faraday shield 304, the cooling channels 340, etc.) may weaken the dielectric window 300. Accordingly, providing the Faraday shield 304 and the cooling channels 340 only in the interior region 328 and cooling the outer region 332 with air maximizes the structural integrity of the dielectric window 300 in the outer region 332.

The cooling channels 340 may be configured to optimize temperature control of the dielectric window 300. For example, characteristics of the cooling channels 340 that may be configured including, but are not limited to, a diameter of the cooling channels 340, a number of the cooling channels 340, a shape (e.g., a cross-section, a layout or pattern, etc.) of the cooling channels 340, a fractal pattern of the cooling channels, etc. For example, the pattern of the cooling channels 340 is configured to achieve a uniform residence time of the coolant across different zones of the cooling channels 340. Other parameters that may be configured to optimize temperature control include, but are not limited to, a flow rate of the coolant through the cooling channels 340, a height (i.e., thickness) of the Faraday shield 304, etc. In some examples, the cooling channels 340 may be embedded or otherwise defined (e.g., engraved) directly within the dielectric window 300. In some examples where the cooling channels 340 are provided within the dielectric window 300, the Faraday shield 304 may be omitted.

One example of the cooling channels 340 and supply tubes 348 is shown in more detail in FIGS. 3B and 3C. In this example, the cooling channels 340 include one or more rings (e.g., concentric rings) 364. A plurality of connecting rods (e.g., tubes) 368 provide fluid communication between the rings 364. As shown, the cooling channels 340 include two of the rings 364 (e.g., an inner ring and an outer ring) and eight of the connecting rods 368. In other examples, the cooling channels 340 may include fewer (i.e., one) or more (i.e., three or more) of the rings 364 and fewer or more of the connecting rods 368.

Further optimization of the temperature control can be achieved by modifying parameters of the rings 364 and the connecting rods 368. For example, a quantity of the rings 364 and/or the connecting rods 368 may be varied. Other example parameters that may be varied include, but a not limited to, respective radiuses of the rings 364 and cross-sectional diameters of the rings 364 and/or the connecting rods 368. The cross-sectional diameters of respective ones of the rings 364 may be the same or different.

As shown, the rings 364 are in fluid communication with each other via the connecting rods 368. Accordingly, the same supply tubes 348 supply the coolant to each of the rings 364. In other examples, different sets of the supply tubes 348 may supply the coolant to different rings 364. For example, one set of the supply tubes 348 may be in fluid communication with one of the rings 364 (e.g., the outer ring) while another set of the supply tubes 348 is in fluid communication with another one of the rings 364 (e.g., an inner ring). In this manner, flow of the coolant to different ones of the rings 364 can be separately controlled. Accordingly, respective temperatures of different radial zones of the dielectric window 300 may be separately controlled.

As described above, in some examples one or more of the cooling channels 340 may be embedded or otherwise defined (e.g., engraved, machined, using an additive manufacturing process, etc.) directly within the dielectric window 300, and the Faraday shield 304 may or may not be omitted. As shown in cross-section in FIG. 3D, a single disc-shaped cooling channel or cavity 372 is defined directly within the material (e.g., ceramic) of the dielectric window 300. In other examples two or more of the cooling channels 372 may be defined within the dielectric window 300. For example, the cooling channel 372 may comprises two or more concentric, annular cavities or channels that may or may not be in fluid communication with each other. Although shown as generally flat, in some examples the dielectric window 300 of this example may be dome-shaped as shown in FIGS. 3A and 3C.

Similar to the examples described in FIGS. 3A to 3C, the cooling channel 372 is configured to flow a cooling liquid or coolant to control a temperature of the dielectric window 300. The liquid cooling system 344 supplies the coolant to the cooling channels 340 via one or more of the supply tubes 348. In this example, since the cooling channel 372 is defined directly within the dielectric window 300 (e.g., within a ceramic body of the dielectric window), the supply tubes 348 may comprise a different material (e.g., aluminum) than the cooling channel 372.

Since the cooling channel 372 is formed directly within the dielectric window 300, the coolant is in direct contact with the material of the dielectric window 300 (e.g., the ceramic body of the dielectric window 300). Accordingly, heat transfer contact between the dielectric window 300 and the coolant within the cooling channel 372 is maximized.

The dielectric window 300 may include one or more support columns or islands 376 arranged within the cooling channel 372. In one example, the columns 376 are comprised of a same material (e.g., ceramic) as the dielectric window 300. The columns 376 may be integrally formed with the dielectric window 300 or separately formed and inserted/attached to the dielectric window 300 within the cooling channel 372 (e.g., subsequent to forming the cooling channel 372). The support columns 376 extend from a lower surface 380 of the cooling channel 372 to an upper surface 384 of the cooling channel 732 (i.e., to an underside of the upper surface 320 of the dielectric window 300). In this manner, the columns 376 provide mechanical support for the upper surface 384 of the dielectric window 300. Although shown as cylindrical, in other examples the columns 376 may have different shapes.

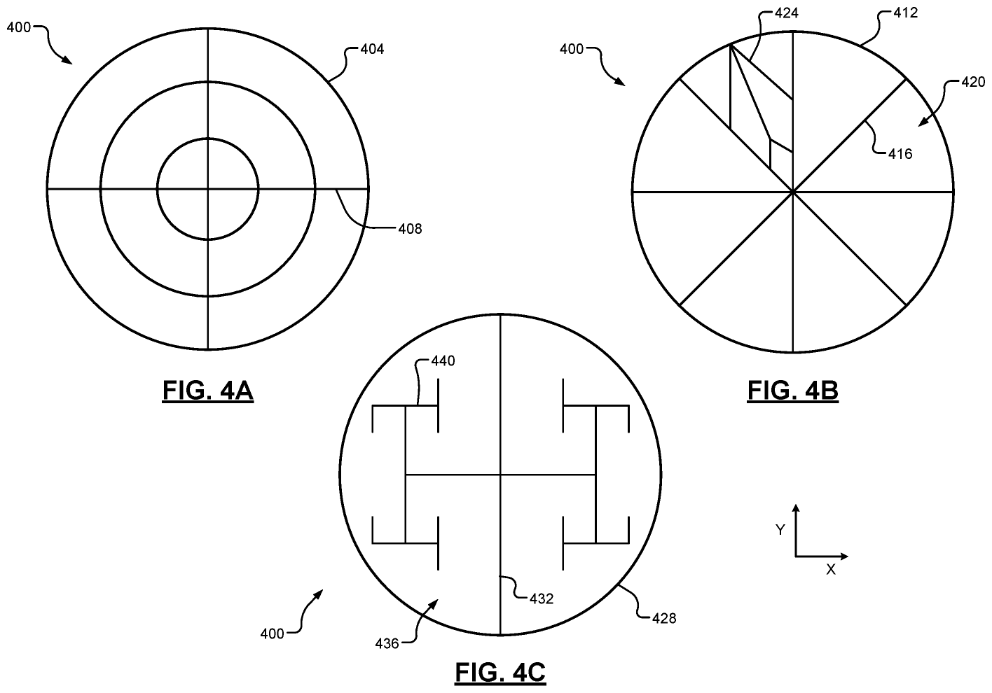

Referring now to FIGS. 4A, 4B, and 4C, example configurations of cooling channels 400 according to the present disclosure are shown. The cooling channels 400 are configured to have a uniform residence time of the coolant liquid across the different zones to minimize a temperature gradient on the dielectric window. The pattern/layout of the cooling channels 400 may incorporate a fractal design to achieve the uniform residence time. In a first configuration shown in FIG. 4A, the cooling channels 400 are arranged in a plurality of rings 404 (e.g., an inner ring, a middle ring, and an outer ring). The rings 404 are in fluid communication with one another via connecting rods 408. Although as shown the rings 404 are uniformly spaced apart, in other examples the rings 404 may be non-uniformly spaced apart.

In a second configuration shown in FIG. 4B, the cooling channels 400 include one or more rings 412 fluidly connected using a plurality of radial connecting rods 416. As shown, the connecting rods 416 are arranged in a spoke-like configuration that define a plurality of azimuthal zones 420. The zones 420 may have a uniform size (as shown) or may be non-uniform. One or more of the zones 420 may include an arrangement of interior connecting rods 424 fluidly connecting adjacent connecting rods 416 to each other and a corresponding segment of the ring 412.

In a third configuration shown in FIG. 4C, the cooling channels 400 include one or more rings 428 bisected by one or more connecting rods 432. As shown, the connecting rod 432 extends in a Y direction in an X-Y plane and bisects the ring 428 into two zones 436 (e.g., left and right zones in an X direction). The connecting rod 432 supplies the coolant to respective cooling channel grids 440 in each of the zones 436.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in a different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application-specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A dielectric window assembly for a substrate processing system, the dielectric window assembly comprising:
a dielectric window;
a Faraday shield, wherein the Faraday shield is one of (i) adjacent to the dielectric window, (ii) embedded within the dielectric window, and (iii) arranged in a recess in an upper surface of the dielectric window; and
cooling channels arranged within the Faraday shield, wherein the cooling channels are configured to flow coolant throughout the Faraday shield.

2. The dielectric window assembly of claim 1, wherein the Faraday shield is adjacent to the dielectric window.

3. The dielectric window assembly of claim 1, wherein the dielectric window includes the recess defined in the upper surface of the dielectric window and the Faraday shield is arranged in the recess.

4. The dielectric window assembly of claim 3, wherein an upper surface of the Faraday shield is coplanar with the upper surface of the dielectric window.

5. The dielectric window assembly of claim 3, wherein an upper surface of the Faraday shield is not coplanar with the upper surface of the dielectric window.

6. The dielectric window assembly of claim 1, wherein the Faraday shield is embedded within the dielectric window.

7. The dielectric window assembly of claim 6, wherein the dielectric window comprises:
a bottom plate;
a top plate; and
a cavity defined between the bottom plate and the top plate,
wherein the Faraday shield is arranged within the cavity between the bottom plate and the top plate.

8. The dielectric window assembly of claim 1, wherein the cooling channels comprise copper tubes.

9. The dielectric window assembly of claim 1, wherein the dielectric window is generally flat.

10. The dielectric window assembly of claim 1, wherein the dielectric window is dome-shaped and includes a generally flat interior region and a curved outer region.

11. A gas distribution assembly including the dielectric window assembly of claim 10 and further comprising a gas plate arranged below the dielectric window, wherein a plenum is defined between the dielectric window and the gas plate.

12. The dielectric window assembly of claim 1, wherein the cooling channels include a plurality of rings and at least one connecting rod that provides fluid communication between individual ones of the plurality of rings.

13. A system comprising the dielectric window assembly of claim 1 and further comprising:
a liquid cooling system in fluid communication with the cooling channels, wherein the liquid cooling system is configured to supply coolant to the cooling channels via a supply tube.

14. The system of claim 13 and further comprising an air cooling system configured to circulate air around an outer region of the dielectric window.

15. A system, comprising:
a dielectric window assembly for a substrate processing chamber, the dielectric window assembly comprising
a dielectric window including an interior region and an outer region,
a Faraday shield, wherein the Faraday shield is arranged in the interior region of the dielectric window and is one of (i) adjacent to the dielectric window, (ii) embedded within the dielectric window, and (iii) arranged in a recess in an upper surface of the dielectric window, and
cooling channels arranged within the Faraday shield, wherein the cooling channels are configured to flow coolant throughout the Faraday shield; and
an air cooling system configured to circulate air around the outer region of the dielectric window.

16. The system of claim 15, wherein the dielectric window is dome-shaped, the interior region is generally flat, and the outer region is curved.

17. The system of claim 15, further comprising a gas plate arranged below the dielectric window, wherein a plenum is defined between the dielectric window and the gas plate.

18. The system of claim 15, wherein the cooling channels include a plurality of rings and at least one connecting rod that provides fluid communication between individual ones of the plurality of rings.

19. The system of claim 15, further comprising a liquid cooling system in fluid communication with the cooling channels, wherein the liquid cooling system is configured to supply coolant to the cooling channels via a supply tube.

20. A dielectric window assembly for a substrate processing system, the dielectric window assembly comprising:
a dielectric window; and
at least one cooling channel arranged within the dielectric window, wherein the cooling channel is configured to flow coolant throughout the dielectric window.

21. The dielectric window assembly of claim 20, wherein the at least one cooling channel comprises a plurality of cooling channels.

22. The dielectric window assembly of claim 20, wherein the cooling channel comprises a disc-shaped cavity defined within a body of the dielectric window.

23. The dielectric window assembly of claim 22, wherein the dielectric window is comprised of ceramic and the cooling channel is defined within the ceramic.

24. The dielectric window assembly of claim 22, further comprising at least one support column arranged within the cooling channel, wherein the at least one support column extends from a lower surface of the cooling channel to an upper surface of the cooling channel.

25. A system, comprising:
the dielectric window assembly of claim 20;
a liquid cooling system in fluid communication with the at least one cooling channel, wherein the liquid cooling system is configured to supply coolant to the at least one cooling channel via a supply tube; and
an air cooling system configured to circulate air around an outer region of the dielectric window.
